(19) United States
(12) Patent Application Publication
(10) Pub. No.: US 2021/0175382 A1
(43) Pub. Date: Jun. 10, 2021

(54) PHOTOVOLTAIC CELL, AND METHOD FOR THE MANUFACTURE THEREOF

(71) Applicant: Sefar AG, Heiden (CH)

(72) Inventors: Peter CHABRECEK, Goldach (CH); Uriel SONDEREGGER, Rheineck (CH); Roland STEIM, Dübendorf (CH)

(73) Assignee: Sefar AG, Heiden (CH)

(21) Appl. No.: 16/613,711

(22) PCT Filed: Apr. 20, 2018
(86) PCT No.: PCT/EP2018/060167

§ 371 Date: Nov. 14, 2019

(30) Foreign Application Priority Data
May 29, 2017 (EP) 17 173 259.7

(51) Int. Cl. H01L 31/05; H01L 31/18

(52) U.S. Cl. CPC H01L 31/0508; H01L 31/1864; H01L 31/0512

(57) ABSTRACT

The invention relates to a photovoltaic cell and a method for the manufacture thereof, comprising a photoelectrically active surface element and at least one conductor track arrangement on at least one surface side of the surface element. According to the invention, in order to form the conductor track arrangement an open woven fabric is applied to the at least one surface side of the photoelectrically active surface element, which woven fabric is woven from electrically conductive threads and transparent, electrically non-conductive threads, wherein the open woven fabric is free of a surface coating.

The invention relates to a method for manufacturing a photovoltaic cell and a novel photovoltaic module comprising a photoelectrically active surface element and at least one conductor track arrangement on at least one surface side of the surface element, according to the preamble of claim 1.

The invention furthermore relates to a photovoltaic cell comprising at least one photoelectrically active surface element and at least one conductor track arrangement on at least one surface side of the surface element, according to the preamble of claim 15.

Solar cells of a very wide range of designs, in particular what are known as thick film or thin film solar cells, have long been known. Solar cells comprise a photoelectrically active surface element which is usually formed using one or more semiconductor materials, in particular silicon. Light striking the surface element generates free charge carriers in the layered surface element. Corresponding steering of the free charge carriers generated in this way makes it possible for a voltage to be generated, which voltage can be used for generating current.

In the case of a plurality of types of solar cells, for the purpose of current generation it is necessary to apply, in particular print, an electrical conductor track arrangement directly onto the photoelectrically active surface side onto which the light strikes. As the size of the conductor track arrangement increases, what is known as the shading also increases, leading to a reduction in the photoelectrically active surface, and thus the power output of a solar cell.

There is a significant need for solar cells having an improved power output, i.e. an increased efficiency. Furthermore, ever more cost-effective solar cells are required on the market, in order that said cells can be used as widely as possible.

It is known to form, for example to print, the conductor track arrangement on a film, and to then apply said film to the photovoltaic surface element, as an electrically conductive substrate.

EP 2 790 196 A1 discloses an electrically conductive substrate for an optoelectronic device, in which a conductor track arrangement is produced by interweaving metal or metallized fibers. In this case, the woven fabric is provided with a partial or full surface coating such that a portion of the woven fabric is exposed and can be used for contacting with an optoelectronic device.

A similar substrate for an optoelectronic device is also known from DE 10 2008 055 969 A1. A photoelectrically active surface element for forming a photovoltaic cell can be applied to substrates of this kind. In this case, however, it is still necessary to establish good electrical contact with the surface of the photoelectrically active surface element. This is associated with additional effort and can lead to a decrease in the efficiency.

A generic method of the type in question is disclosed in WO 201 6/1 56 276 A1. A woven conductor track arrangement comprising fusible polymer threads is used. Said threads are liquefied by means of heat treatment, in order to form a cladding layer.

It is known from EP 2 660 878 A1 and U.S. Pat. No. 3,255,047 A to fix a woven fabric with an electrical conductor track arrangement by means of electrical contact points consisting of a solder paste.

JP 2006 165 149 A1 teaches fixing a woven conductor track arrangement by means of an additional adhesive layer.

The object of the invention is to specify a photovoltaic cell and a method for the manufacture thereof, by means of which a photovoltaic cell having particularly high efficiency and a method for efficient manufacture of photovoltaic cells of this kind and of a novel photovoltaic module is achieved.

The object is achieved according to the invention by a method having the features of claim 1, a photovoltaic cell having the features of claim 14, and a woven fabric for a photovoltaic cell having the features of claim 15. Preferred embodiments of the invention are specified in the dependent claims.

The method according to the invention is characterized in that, in order to form the conductor track arrangement an open woven fabric is applied to the at least one surface side of the photoelectrically active surface element, which woven fabric is woven from electrically conductive threads and transparent, electrically non-conductive threads, wherein the open woven fabric is free of a surface coating.

A basic concept of the invention consists in using an open woven fabric, i.e. an uncoated woven fabric, in order to form the conductor track arrangement on a surface side of a photoelectrically active surface element. In this case, the woven fabric is applied directly to the surface side of the photoelectrically active surface element. As a result, the work step of manufacturing a substrate comprising a continuous coating, as is known from the prior art, can be omitted. The woven fabric is constructed in a very simple manner, which, owing to the open structure and the use of transparent non-conductive threads, leads to good transparency and thus a good energy yield of the photoelectrically active surface element. The woven fabric can preferably be arranged on the front face of the two surface sides that is exposed to the light. In the case of new IBC SHJ solar cells, the woven fabric can also be applied only to the rear face of the surface element.

A preferred embodiment of the invention consists in the open woven fabric being formed by fusible threads at least in part, and heat treatment being performed following the application of the open woven fabric, in which heat treatment the fusible threads are fused at least in part, wherein the open woven fabric is firmly bonded, by the fused threads, to the surface element. Following application of the woven fabric, said fabric can thus be easily fixed to the surface side of the surface element. In this case, at least some of the threads used in the woven fabric can fuse, at least at the surface region thereof. In this case, the fused material constitutes a close connection to the surface of the surface element, wherein the woven fabric reliably adheres to the surface side of the surface element, at least in regions.

According to a development of the invention, it is particularly preferable for the non-conductive threads to be formed by a thermoplastic polymer material, in particular a thermoplastic olefin, which fuses at least in part. The thermoplastic polymer material can in particular comprise PP, POE, PA, PET, PEN or the like. The diameters of the non-conductive threads can preferably be in a range of between 10 μm and 200 μm or greater. The polymer threads are preferably transparent.

In principle, only the non-conductive threads can be fused. However, a preferred development of the invention consists in the electrically conductive threads being formed of a metal or a metal alloy having a low melting or softening temperature, in particular of below 200° C., and fusing at least in part. It is thus possible to fuse only the electrically conductive threads or both the conductive and non-conductive threads during the heat treatment. This leads to a particularly close connection to the surface of the surface element. The fusing of the metal conductive threads also leads to improved contacting and thus a reduction in the internal resistance of the photovoltaic cell. The metal threads may comprise a solid material or are provided with a fusible metal coating. A fusible material may be an alloy of Cu/InSn, Cu/Sn, CU/SBA or the like. Preferably a tin alloy (Sn alloy) can be applied by means of hot-dip tinning.

According to a development of the invention, it is particularly advantageous for threads to come directly into contact with the surface of the surface element and for a contact surface between the threads and the surface of the surface element to increase upon fusion. In particular when using fusible conductive threads, it is thus possible for a contact surface to the surface element to be designed so as to be larger and particularly close. This allows for particularly low-resistance voltage or current tapping.

The heat treatment can be performed at a suitable temperature. According to a development of the invention, it is particularly preferable for a temperature of 250° C., in particular of 200° C., not to be exceeded during the heat treatment. The temperature of the heat treatment is preferably between 140° C. and 200° C. At these relatively low temperatures, thermal damage to the sensitive surface element made of the semiconductor material is prevented. As a result, in particular the method according to the invention is particularly suitable for manufacturing novel solar cells from particularly thermally sensitive materials, in particular silicon heterostructure solar cells.

The heat treatment makes it possible for the open woven fabric to be adequately positioned and fixed on the surface element. According to a variant of the invention, in order to achieve stable fastening, a joining compound is laminated onto the surface element following application of the open woven fabric. In this case the joining compound is transparent, and therefore good transparency is still ensured. In particular, the joining compound may be a thermal polymer or a UV-curable polymer or polymer mixture, such as is provided for the use of the electrically non-conductive threads, or a fluoropolymer, or silicone.

A further improvement is achieved, according to the invention, in that a transparent cover layer, in particular a glass, is applied to the surface element following the application of the open woven fabric. The transparent cover layer can be provided together with or without the joining compound. It is preferable, however, for the transparent cover layer to be applied together with the joining compound, to the surface side of the surface element comprising the open woven fabric. As a result, particularly good protection and a particularly robust surface of the photovoltaic cell is achieved.

It is furthermore preferable, according to the invention, for the open woven fabric to comprise a contact side, along which a substantial part of the electrically conductive threads extend. In particular, the woven fabric can be provided with a twill, in particular woven having a twill of 5:1 or 3:1. Twills of up to 11:1 or more are also possible, wherein the electrically conductive threads run over a plurality of adjacent threads, on the contact side of the open woven fabric, and thus form a particularly large contact region.

In principle, other suitable woven fabrics and binder systems may also be provided. According to a development of the invention, it is particularly advantageous for the electrically conductive threads to be woven in the weft and/or warp direction, in the open woven fabric. In the case of weaving only in the weft or warp direction, electrical conductor tracks are provided which extend so as to be substantially in parallel. Weaving electrically conductive threads in the weft and in the warp direction makes it possible to achieve a pattern or grid-like conductor track arrangement in the open woven fabric. This may be advantageous for particular solar cell assemblies.

In principle, the photoelectrically active surface element may be any optoelectrical or optoelectronic element that preferably converts light energy into electrical energy. In this case, any conventional structure for a solar cell may be provided, in particular what are known as Al-BSF, PERC-/PERT-/PERL cells, or other solar cells. A particularly advantageous development of the method according to the invention consists in a silicon heterostructure solar cell, also known as a SHJ solar cell, being provided as the photoelectrically active surface element. Solar cells of this kind represent a new generation of solar cells and have an increased level of efficiency. Solar cells of this kind are particularly heat-sensitive.

According to a development of the invention, the conductor track arrangement comprising the open woven fabric is applied to one or both sides of the surface element. In particular in the case of single-sided application, the conductor track arrangement can be provided on the surface side of the surface element that is exposed to the light. In the same way, a second conductor track arrangement can also be arranged on the lower face of the surface element, in particular in the case of what are known as bifacial cells. Preferably, in the case of new IBC SHJ solar cells, the woven fabric comprising the conductor track arrangement can also be applied only on the lower or rear face remote from the light.

For the purpose of a particularly expedient connection to a photovoltaic module, according to a variant of the method according to the invention it is preferable for a plurality of surface elements to be connected to one photovoltaic module by means of one or more woven fabrics. In this case, the open woven fabric may be many times larger than a single photovoltaic cell. In this case, the electrically conductive threads may extend only on one side of the woven fabric or, preferably, alternatively, first on one and then on the other side of the woven fabric (FIG. 3). Woven fabrics of this kind having alternating conductive contact sides are particularly sought-after for the Z-wiring of the cells in one module. The open woven fabric can contact and interconnect a plurality of mutually adjacent photocells. This may be on one surface side or alternately between a front and a rear face of the adjacent cells. In this case the open woven fabric not only constitutes a conductive electrical connection between mutually adjacent solar cells, but rather also connects said cells in a mechanical manner.

With respect to a photovoltaic cell, the object mentioned at the outset is also achieved in that, in order to form the conductor track arrangement, an open woven fabric is applied directly to the at least one surface side of the surface element, which woven fabric is woven from electrically conductive threads and transparent, electrically non-conductive threads. The photovoltaic cell is in particular manufactured according to one of the methods described above, wherein the corresponding advantages also result.

Furthermore, according to the invention a woven fabric is also provided, which fabric is characterized in that it is an open woven fabric that is woven from electrically conductive threads and transparent, electrically non-conductive threads, and in that at least some of the threads are fusible at a temperature of below 200° C. The woven fabric can in particular be used for the above-described photovoltaic cell or for the above-described method according to the invention.

For forming the woven fabric, a wire made of a conductive metal or having a conductive metal coating and having a diameter of between 70 μm and 300 μm is preferably provided as the electrically conductive thread. The electrically non-conductive thread preferably has a diameter of between 20 μm and 200 μm, in particular between 30 μm and 70 μm. Said thread is manufactured from a transparent polymer material, in particular PEN, PP, POE and PA or PET, having a transparency of 95% and above, in particular over 99%. The thread count in the warp direction is preferably 40 to 60 threads per cm, and in the weft direction it is preferably also 40 to 60 threads per cm. In this case, the woven fabric is essentially formed of the non-conductive transparent threads, wherein the electrically conductive threads are provided at a spacing of between 0.5 mm and 15 mm, preferably between 1 mm and 8 mm. In particular a twill, preferably of from 5/1 to 11/1 or 3/3 is provided as the weave.

In this case, according to a development of the invention, it is particularly advantageous for the electrically conductive threads to protrude outwards relative to the non-conductive threads by a defined amount, wherein the amount is preferably between 10 and 20 μm.

As a result, improved contact between the electrically conductive threads and the surface side of the surface element can be achieved. The thickness of the woven fabric is preferably between 100 μm and 400 μm.

The invention will be described further in the following, on the basis of preferred embodiments which are shown schematically in the drawings. In the drawings:

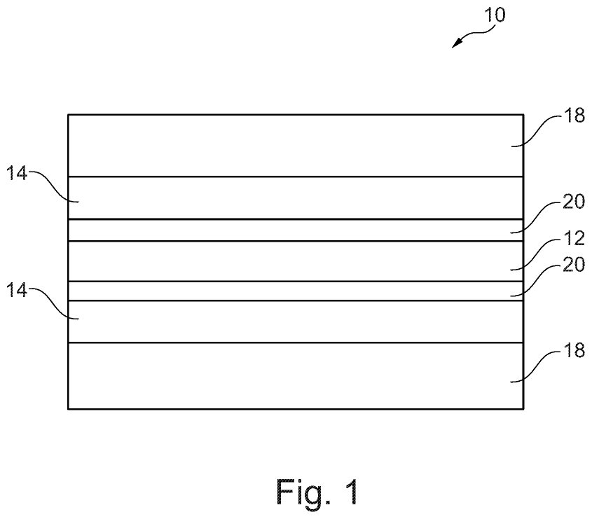

FIG. 1 shows a structure of a photovoltaic cell manufactured according to the invention;

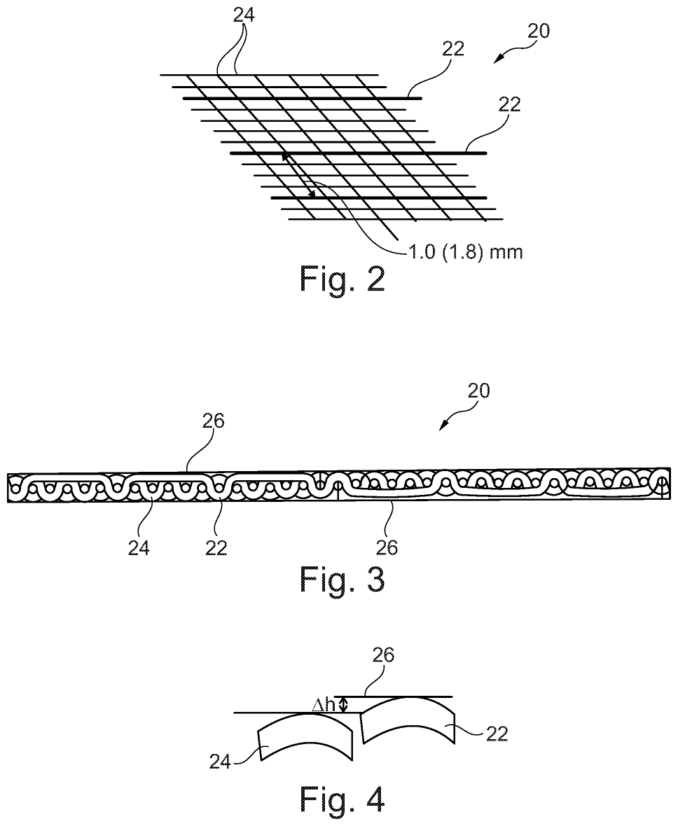

FIG. 2 is a view of a woven fabric for the photovoltaic cell according to the invention;

FIG. 3 is an enlarged cross-sectional view through a woven fabric for the invention;

FIG. 4 is a schematic cross-sectional view for constructing a woven fabric for the invention;

FIG. 5 shows a first joining arrangement for joining a plurality of photovoltaic cells to a woven fabric; and

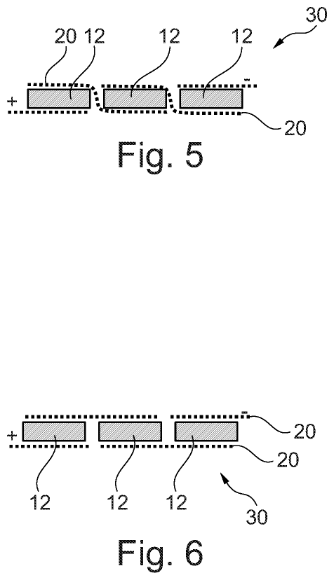

FIG. 6 shows a second joining arrangement for joining photovoltaic cells.

A photovoltaic cell according to the invention is shown in FIG. 1. Said cell comprises a photoelectrically active surface element 12 as a substantial part thereof. The surface element 12 is formed, in a known manner, from a semiconductor material, in particular a silicon material, in a layer structure, wherein charge carriers are displaced when light energy impinges. The surface element 12 can in particular be a silicon heterostructure solar cell.

In order to tap electrical charge carriers or a voltage at the two surface sides of the surface element 12, according to the invention an open woven fabric 20 is applied in each case. According to FIG. 2, the woven fabric 20 comprises non-conductive threads 24 and electrically conductive threads 22 which form a conductor track arrangement.

After the open woven fabric 20 has been applied or placed on, heat treatment is performed in a temperature range of preferably between 140° C. and 180° C. In this case, both the conductive threads 22 and the non-conductive threads 24 of the woven fabric 20 fuse and form an enlarged contact surface and a firm connection to the surface of the surface element 12.

Subsequently, a joining compound 14, in particular consisting of a plastics or adhesive material, is laminated on, in a fused or flowable state. Subsequently, a cover layer 18 or a UV-stable polymer, such as Teflon or silicone, in particular a glass, is applied to the joining compound 14, on both sides of the surface element 12. When the joining compound 14 cures, the cover layer 18, in particular a see-through glass material, is firmly connected, such that a robust outer protective layer for the photovoltaic cell 10 is provided thereby.

An open woven fabric 20 according to the invention is woven from electrically conductive threads 22 and electrically non-conductive threads 24 made of a polymer material. In the case of the open woven fabric 20 according to the invention, no continuous coating or other layer coating is provided, and therefore gaps and passages through the woven structure still exist. In the case of the woven fabric 20 shown, the electrically conductive threads 22, in the form of metal wires, are woven together at a spacing of from 1 mm to 1.8 mm. Non-conductive threads 24 consisting of a transparent and thermoplastic olefin are provided as warp threads and intermediate weft threads. A total of 60 threads 22, 24 per cm are woven in the warp and in the weft direction.

FIG. 3 shows a possible woven fabric weave having a twill of 5:1. In this case, one electrically conductive thread 22 in the weft direction overlaps five electrically non-conductive warp threads 24 in each case, before a thread loop is formed. In this case, elongate, and thus large-surface, contact regions of the electrically conductive thread 22 result on a contact side 26 of the woven fabric 20. In this case, the woven fabric 20 according to FIG. 3 has the particularity that both sides are formed as contact sides 26, wherein the twill alternates, at specified points, from one contact side 26 to the other contact side 26. Said alternating arrangement in a woven fabric 20 is advantageous in particular for a photovoltaic module 30 comprising a plurality of surface elements 12, as is shown in FIG. 5. In this case, a continuous woven fabric 20 loops, alternately in each case, around the front and rear faces of the surface elements 12 which adjoin one another, such that contact regions that alternate in each case are necessary.

It is also possible, however, for a woven fabric 20 according to the invention to be formed having just one contact side 26, in which the electrically conductive threads 22 extend substantially along the one contact side 26. Such a design of the woven fabric is suitable in particular for a photovoltaic module 30 according to FIG. 6, in which one woven fabric 20 in each case is applied to one side each of an arrangement consisting of a plurality of surface elements 12. Following the contacting by the woven fabric or fabrics 20, the joining compound 14 and the cover layer 18 can be applied.

When forming a woven fabric 20 according to the invention, it is expedient and advantageous in particular on the contact side 26 for the conductive threads 22 to protrude outwards, relative to the adjacent non-conductive threads 24, by a defined amount Δh, as is clearly shown in FIG. 4. Said amount of the protrusion of the electrically conductive threads 22 is in particular between 10 μm and 50 μm.

1. A method for manufacturing a photovoltaic cell
comprising
a photoelectrically active surface element and
at least one conductor track arrangement on at least one surface side of the surface element,
wherein
in order to form the conductor track arrangement an open woven fabric is applied to the at least one surface side of the photoelectrically active surface element, which woven fabric is woven from electrically conductive threads and transparent, electrically non-conductive threads, wherein the open woven fabric is free of a surface coating, and
the open woven fabric is formed having fusible threads at least in part, wherein
the electrically non-conductive threads have a diameter of from 30 μm to 70 μm, and the electrically conductive threads have a diameter of from 70 μm to 300 μm, wherein the electrically conductive threads protrude outwards, by a defined amount, relative to the non-conductive threads,
the electrically non-conductive threads are formed using a thermoplastic polymer material,
a heat treatment is performed following the application of the open woven fabric, in which heat treatment the fusible threads are fused at least in part, wherein the open woven fabric is firmly bonded, by the partially fused threads, to the surface element and fixed thereon, and
a transparent cover layer is applied to the fixed open woven fabric.

2. The method according to claim 1,
wherein
a thread count of the open woven fabric in the warp direction and in the weft direction is 40 to 60 threads per cm.

3. The method according to claim 1,
wherein
the non-conductive threads are formed using a thermoplastic olefin which fuses in part.

4. The method according to claim 1,
wherein
the electrically conductive threads are formed of a metal or a metal alloy having a low melting or softening temperature, in particular of below 200° C., and fuse at least in part.

5. The method according to claim 2,
wherein
threads come directly into contact with the surface of the surface element and a contact surface between the threads and the surface of the surface element increases upon fusion.

6. The method according to claim 1,
wherein
a temperature of 250° C., in particular of 200° C., is not exceeded during the heat treatment.

7. The method according to claim 1,
wherein
a joining compound is laminated onto the surface element following application of the open woven fabric.

8. The method according to claim 1,
wherein
a glass is applied to the surface element as the transparent cover layer.

9. The method according to claim 1,
wherein
the open woven fabric comprises a contact side, along which a substantial part of the electrically conductive threads extend.

10. The method according to claim 1,
wherein
the electrically conductive threads are woven in the weft and/or warp direction in the open woven fabric.

11. The method according to claim 1,
wherein
a silicon heterostructure solar cell (SHJ solar cell) is provided as the photoelectrically active surface element.

12. The method according to claim 1,
wherein
the conductor track arrangement comprising the open woven fabric is applied to one or both sides of the surface element.

13. The method according to claim 1,
wherein
a plurality of surface elements is connected to one photovoltaic module by means of one or more woven fabrics.

14. The method according to claim 1,
wherein
the electrically conductive threads have a spacing of from 1 mm to 8 mm from one another.

15. A photovoltaic cell and/or module comprising at least one photoelectrically active surface element and at least one conductor track arrangement on at least one surface side of the surface element, manufactured according to the method according to claim 1,
wherein
in order to form the conductor track arrangement, an open woven fabric is applied directly to the at least one surface side of the surface element, which woven fabric is woven from electrically conductive threads and transparent, electrically non-conductive threads which are fusible at least in part,
the electrically non-conductive threads have a diameter of from 30 μm to 70 μm, and the electrically conductive threads have a diameter of from 70 μm to 300 μm, wherein the electrically conductive threads protrude outwards, by a defined amount, relative to the non-conductive threads,
the electrically non-conductive threads are formed using a thermoplastic polymer material, and
following the application of the open woven fabric, the threads are fused in part by means of heat treatment, wherein the open woven fabric is firmly bonded and fixed to the surface element.
